(19) United States
(12) Patent Application Publication
(10) Pub. No.: US 2013/0040440 A1
(43) Pub. Date: Feb. 14, 2013

(54) EPITAXIAL PROCESS WITH SURFACE CLEANING FIRST USING HCl/GeH4/H2SiCl2

(71) Applicants: Thomas N. Adam, Slingerlands, NY (US); Hong He, Schenectady, NY (US); Alexander Reznicek, Mount Kisco, NY (US); Devendra K. Sadana, Pleasantville, NY (US); Paul D. Brabant, Schodack, NY (US); Keith Chung, Guilderland, NY (US); Manabu Shinriki, Albany, NY (US)

(72) Inventors: Thomas N. Adam, Slingerlands, NY (US); Hong He, Schenectady, NY (US); Alexander Reznicek, Mount Kisco, NY (US); Devendra K. Sadana, Pleasantville, NY (US); Paul D. Brabant, Schodack, NY (US); Keith Chung, Guilderland, NY (US); Manabu Shinriki, Albany, NY (US)

(73) Assignee: INTERNATIONAL BUSINESS MACHINES CORPORATION, Armonk, NY (US)

(21) Appl. No.: 13/613,003

(22) Filed: Sep. 13, 2012

Related U.S. Application Data
(63) Continuation of application No. 13/206,248, filed on Aug. 9, 2011.

(51) Int. Cl. H01L 21/20

(52) U.S. Cl. 438/478; 257/E21.09

(57) ABSTRACT

A method of depositing an epitaxial layer that includes chemically cleaning the deposition surface of a semiconductor substrate and treating the deposition surface of the semiconductor substrate with a hydrogen containing gas at a pre-bake temperature. The hydrogen containing gas treatment may be conducted in an epitaxial deposition chamber. The hydrogen containing gas removes oxygen-containing material from the deposition surface of the semiconductor substrate. The deposition surface of the semiconductor substrate may then be treated with a gas flow comprised of at least one of hydrochloric acid (HCl), germane (GeH₄), and dichlorosilane (H₂SiCl₂) that is introduced to the epitaxial deposition chamber as temperature is decreased from the pre-bake temperature to an epitaxial deposition temperature. At least one source gas may be applied to the deposition surface for epitaxial deposition of a material layer.

### CROSS REFERENCE TO RELATED APPLICATION

This application is a continuation of U.S. patent application Ser. No. 13/206,248, filed Aug. 9, 2011, the entire content and disclosure of which is incorporated herein by reference.

### BACKGROUND

The present disclosure relates generally to epitaxial deposition processes. More particularly, the present disclosure relates to pre-clean processes for use with epitaxial deposition.

Epitaxial growth technology is widely applied in manufacturing of semiconductor devices, such as a metal oxide semiconductor (MOS) transistor. Typically, when selective epitaxial growth technology is used to form an epitaxial layer on a semiconductor substrate, the crystalline orientation of the epitaxial layer is almost the same as that of the semiconductor substrate. Before the epitaxial layer is deposited on the substrate, a surface cleaning process is typically performed to remove native oxides and/or other impurities from the deposition surface, e.g., surface of the semiconductor substrate. The surface cleaning process is typically employed to increase the quality of the epitaxial layer being formed.

### SUMMARY

The present disclosure provides an epitaxial deposition process that includes surface cleaning of the deposition surface with a gas flow comprised of at least one of hydrochloric acid (HCl), germane (GeH₄), and dichlorosilane (H₂SiCl₂). In one embodiment, the epitaxial deposition process includes positioning a semiconductor substrate in an epitaxially deposition chamber. A deposition surface of the semiconductor substrate is then treated with a hydrogen containing gas at a pre-bake temperature, wherein the hydrogen containing gas removes oxygen containing material from the deposition surface of the semiconductor substrate. The deposition surface of the semiconductor substrate is then treated with a gas flow comprised of at least one of hydrochloric acid, germane, and dichlorosilane that is introduced to the epitaxial deposition chamber as temperature is decreased from the pre-bake temperature to the epitaxial deposition temperature. The source gasses for epitaxial deposition of a material layer are then applied to the deposition surface.

In another embodiment, the epitaxial deposition process includes chemically cleaning the deposition surface of a semiconductor substrate. The deposition surface of the semiconductor substrate may then be treated with a hydrogen containing gas at a pre-bake temperature, wherein the hydrogen containing gas removes oxygen containing material from the deposition surface of the semiconductor substrate. The deposition surface of the semiconductor substrate is then treated with a gas flow comprised of at least one of hydrochloric acid, germane, and dichlorosilane that is introduced to the epitaxial deposition chamber as temperature is decreased from the pre-bake temperature to the epitaxial deposition temperature. The source gasses for epitaxial deposition of a material layer are then applied to the deposition surface.

In yet another embodiment, the epitaxial deposition process includes positioning a semiconductor substrate in an epitaxially deposition chamber. The deposition surface of the semiconductor substrate is then treated with a hydrogen containing gas at a temperature greater than 750° C., wherein the hydrogen containing gas removes oxygen containing material from the deposition surface of the semiconductor substrate. The deposition surface of the semiconductor substrate is then treated with a gas flow comprised of at least one of hydrochloric acid, germane, and dichlorosilane that is introduced to the epitaxial deposition chamber as temperature is decreased to less than 500° C. The source gasses for epitaxial deposition of a material layer are then applied to the deposition surface.

### BRIEF DESCRIPTION OF SEVERAL VIEWS OF THE DRAWINGS

The following detailed description, given by way of example and not intended to limit the disclosure solely thereto, will best be appreciated in conjunction with the accompanying drawings, wherein like reference numerals denote like elements and parts, in which:

FIG. 1 is a flow chart of an epitaxial deposition process that includes surface cleaning of a deposition surface of a semiconductor substrate with a gas flow comprised of at least one of hydrochloric acid, germane, and dichlorosilane, in accordance with one embodiment of the present disclosure.

FIG. 2 is a plot of film thickness (Å) vs. time (seconds) for epitaxial growth of silicon germanium (SiGe) following a pre-bake cleaning process in a hydrogen (H₂) atmosphere, a pre-bake cleaning process in a helium (He) atmosphere, and a cleaning process in an atmosphere including a gas flow comprised of at least one of hydrochloric acid, germane, and dichlorosilane, in accordance with one embodiment of the present disclosure.

FIG. 3 is a plot of film thickness (Å) vs. time (seconds) for epitaxial growth of silicon germanium following a cleaning process in an atmosphere that does not include hydrochloric acid, germane, and dichlorosilane, a cleaning process in an atmosphere that includes 500 sccm hydrochloric acid and 45 sccm germane, a cleaning process in an atmosphere that includes 500 sccm hydrochloric acid and 175 sccm germane, a pre-bake cleaning process in an atmosphere that includes 500 sccm hydrochloric acid, 175 sccm germane, and 50 sccm dichlorosilane, in accordance with one embodiment of the present disclosure.

FIG. 4A is a plot of x-ray diffraction (XRD) of an epitaxially grown silicon germanium layer with a growth time of 450 seconds formed after a cleaning process in an atmosphere that does not include hydrochloric acid and germane.

FIG. 4B is a plot of x-ray diffraction of an epitaxially grown silicon germanium layer with a growth time of 900 seconds formed after a cleaning process in an atmosphere that does not include hydrochloric acid and germane.

FIG. 5A is a plot of x-ray diffraction of an epitaxially grown silicon germanium layer with a growth time of 450 seconds formed after a pre-bake cleaning process in an atmosphere that includes 500 sccm hydrochloric acid and 175 sccm germane, in accordance with one embodiment of the present disclosure.

FIG. 5B is a plot of x-ray diffraction of an epitaxially grown silicon germanium layer with a growth time of 900 seconds formed after a cleaning process in an atmosphere that includes 500 sccm hydrochloric acid and 175 sccm germane, in accordance with one embodiment of the present disclosure.

FIG. 6A is a plot of x-ray diffraction of an epitaxially grown silicon germanium layer with a growth time of 450 seconds formed after a cleaning process in an atmosphere that includes 500 sccm hydrochloric acid, 175 sccm germane and 50 sccm dichlorosilane, in accordance with one embodiment of the present disclosure.

FIG. 6B is a plot of x-ray diffraction of an epitaxially grown silicon germanium layer with a growth time of 900 seconds formed after a pre-bake cleaning process in an atmosphere that includes 500 sccm hydrochloric acid, 175 sccm germane and 50 sccm dichlorosilane, in accordance with one embodiment of the present disclosure.

### DETAILED DESCRIPTION

Detailed embodiments of the methods and structures of the present disclosure are described herein; however, it is to be understood that the disclosed embodiments are merely illustrative of the disclosed methods that may be embodied in various forms. In addition, each of the examples given in connection with the various embodiments of the disclosure are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

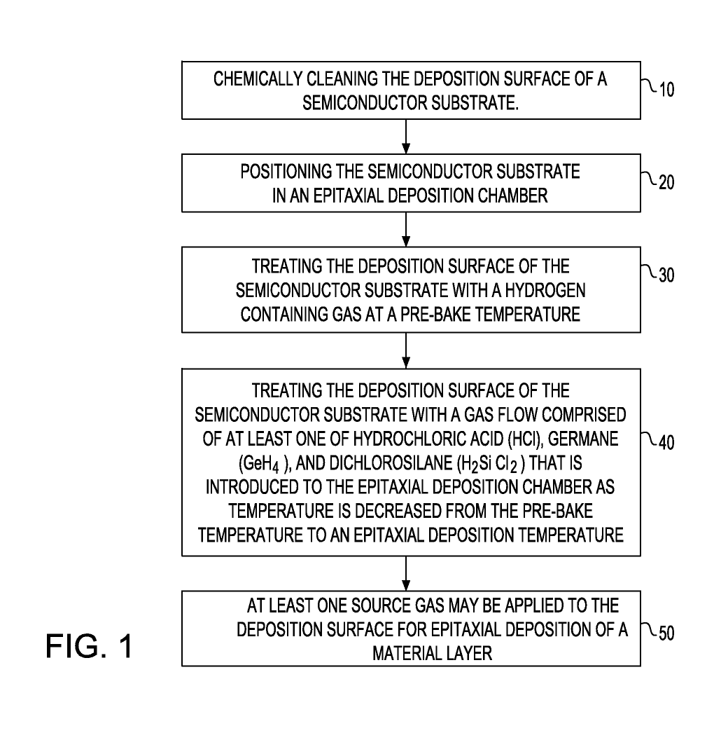

The present disclosure is directed towards epitaxial deposition. “Epitaxially forming, epitaxial growth and/or epitaxial deposition” mean the growth of a semiconductor material on a deposition surface of a semiconductor material, in which the semiconductor material being grown has the same crystalline characteristics as the semiconductor material of the deposition surface. Epitaxially growth typically requires an atomically clean deposition surface. In some embodiments, prior to epitaxial growth the deposition surface, e.g., surface of a semiconductor substrate, is treated with a pre-bake step in a hydrogen (H₂) gas, wherein the pre-bake step can remove the native oxide from the silicon surface. It has been determined by the Applicant's of the present disclosure that hydrogen from the pre-bake step bonds to the deposition surface via silicon-hydrogen bonds. The silicon-hydrogen bonds formed on the deposition surface may adversely impact epitaxial growth of the material layer being deposited. In one embodiment, the methods disclosed herein reduce the formation of silicon-hydrogen bonds on the deposition surface that results from the hydrogen gas atmosphere of the pre-bake process by flowing a gas comprised of at least one of hydrochloric acid, germane, and dichlorosilane through the epitaxial deposition chamber prior to deposition. More specifically and in one embodiment, to reduce the formation of silicon hydrogen bonds on the deposition surface, the gas flow comprised of at least one of hydrochloric acid, germane, and dichlorosilane is flown through the epitaxial deposition chamber during a cool down stage that is before the application of the source gasses for epitaxial deposition and after the pre-bake process that removes oxygen from the deposition surface. The details of the epitaxial deposition process including surface cleaning of the deposition surface with a gas flow comprised of at least one of hydrochloric acid, germane, and dichlorosilane is now discussed in greater detail with reference to FIG. 1.

FIG. 1 is a flow chart of one embodiment of an epitaxial deposition process that includes surface cleaning of the deposition surface of a semiconductor substrate with a gas flow comprised of at least one of hydrochloric acid, germane, and dichlorosilane. It is noted that the methods of the present disclosure are not limited to the steps included in the flow chart depicted in FIG. 1, as any number of preliminary, intermediate and subsequent process steps may be employed, so long as being incorporated within a method that includes surface cleaning of a semiconductor substrate with a gas flow comprised of at least one of hydrochloric acid, germane, and dichlorosilane.

In one embodiment, the epitaxial deposition process may begin with the step 10 of chemically cleaning the deposition surface of a semiconductor substrate. The semiconductor substrate employed in the present disclosure may be composed of any silicon containing material including, but not limited to, silicon (Si), silicon germanium (SiGe), silicon doped with carbon (Si:C), silicon germanium doped with carbon (SiGe:C) and combinations thereof. The semiconductor substrate may also comprise an organic semiconductor or a layered semiconductor, such as silicon/silicon germanium, a silicon-on-insulator (SOI) or a silicon germanium-on-insulator (SGOI). In one example, the semiconductor substrate is composed of a silicon (Si), i.e., substantially 100% silicon. The semiconductor substrate may also be composed of a compound semiconductor, such as a semiconductor material composed of a III-V semiconductor material. Moreover, the semiconductor substrate may include surfaces with any crystallographic orientation including, e.g., (100), (110), (111) or any suitable combination thereof.

The semiconductor substrate may be doped, undoped or contain doped and undoped regions therein. Further, the semiconductor substrate may be strained, unstrained or any combination thereof. In one embodiment, the semiconductor substrate may include at least one well region. For example, when a semiconductor substrate is subsequently processed to provide at least one n-type field effect transistor (nFET), a well region is present in the semiconductor substrate doped to a p-type conductivity. In one example, in which the semiconductor substrate is subsequently processed to provide at least one p-type field effect transistor (pFET), a well region may be present in the semiconductor substrate that is doped to an n-type conductivity.

In one embodiment, the surface of the semiconductor substrate is typically cleaned to remove any residual layers, foreign particles, and any residual metallic surface contamination. In one embodiment, the chemical cleaning process includes a first step of treating the deposition surface of the semiconductor substrate with hydrofluoric acid (HF), a second step of treating the deposition surface of the semiconductor substrate solution of ammonium hydroxide (NH₄OH) and hydrogen peroxide (H₂O₂) and a third step of treating the deposition surface with an aqueous mixture of hydrochloric acid (HCI) and an oxidizing agent selected from the group consisting of hydrogen peroxide, ozone (O₃) and combinations thereof. The cleaning steps that include the application of the solution of ammonium hydroxide and hydrogen peroxide and the aqueous mixture of hydrochloric acid and the oxidizing agent may be provided by an RCA clean sequence.

In one embodiment and in the first step of the cleaning process, oxide material, such as silicon oxide or silicon oxynitride, is removed from the deposition surface of the semiconductor substrate by the application of a solution of hydrofluoric acid. Hydrofluoric acid is used to etch silicon oxide (SiO₂) films on silicon substrates, because the hydrofluoric acid will etch the silicon oxide without attacking the silicon surface. The hydrofluoric acid it typically diluted with deionized (DI) water in order to slow down the etch rate of the silicon oxide, thereby ensuring better etch uniformity. In one embodiment, the dilution ratio ranges from 1:1 HF:H₂O to 300:1 H₂O:HF. In another embodiment, the hydrofluoric acid may be diluted with ammonium fluoride (NH₄F).

Following the surface treatment with hydrofluoric acid, the removal of particles and residual metallic contamination continues with an RCA clean process, which in some embodiments provides the second and third steps of the chemical cleaning process. In one embodiment, the RCA clean includes a treatment of the semiconductor substrate in a solution of ammonium hydroxide and hydrogen peroxide followed by an aqueous mixture of hydrochloric acid and an oxidizing agent (e.g., H₂O₂, O₃).

The first step of the RCA clean that includes ammonium hydroxide and hydrogen peroxide may be referred to as “SC-1” (standard clean #1). SC-1 includes of a mixture of ammonium hydroxide and hydrogen peroxide and deionized water. A typical concentration ratio for the mix is 1:1:5 NH₄OH:H₂O₂:H₂O, although ratios as low as 0.05:1:5 are suitable for cleaning the semiconductor substrate. SC-1 typically operates in a temperature ranging from 50° C. to 70° C.

The second step of the RCA clean that includes the aqueous mixture of hydrochloric acid and an oxidizing agent may be may be referred to as “SC-2” (standard clean #2). SC-2 includes a mixture of hydrochloric acid, hydrogen peroxide, and deionized water. A typical concentration ratio for the mix is 1:1:5 HCl:H₂O₂:H₂O. SC-2 is typically operated in the temperature range of 50-70° C.

In one embodiment, the above-described chemical cleaning process is suitable for providing a deposition surface of a semiconductor substrate that is to be treated with a subsequently described high temperature pre-bake cleaning process that is conducted in an epitaxial deposition chamber with a hydrogen (H₂) atmosphere. By “high temperature” it is meant that the pre-bake cleaning process is conducted at a temperature that is greater than 1000° C. The temperatures described herein are measured at the deposition surface of the semiconductor substrate. In some embodiments, the above described chemical cleaning process may be omitted before the high temperature pre-bake cleaning process. For example, if the pre-bake cleaning process is sufficient by itself to remove native oxide from the semiconductor substrate, that chemical cleaning process may be omitted.

In another embodiment, the chemical cleaning process is provided by a hydrofluoric acid last process. In this embodiment, oxide material, such as silicon oxide or silicon oxynitride, is removed from the deposition surface of the semiconductor substrate by the application of a solution of hydrofluoric acid. The hydrofluoric acid is typically diluted with deionized water in order to slow down the etch rate of the silicon oxide, thereby ensuring better etch uniformity. In one embodiment, the dilution ratio ranges from 1:1 HF:H₂O to 300:1 H₂O:HF. In another embodiment, the hydrofluoric acid may be diluted with ammonium fluoride (NH₄F).

The hydrofluoric acid last chemical cleaning process is suitable for providing a deposition surface of a semiconductor substrate that is to be treated with a subsequently described low temperature pre-bake cleaning process that is conducted in an epitaxial deposition chamber with a hydrogen atmosphere. By “low temperature” it is meant that the pre-bake cleaning process is conducted at a temperature ranging from 750° C. to 850°.

The above-described chemical cleaning processes may be applied to the deposition surface of the semiconductor substrate by methods such as immersion within a dip tank, brushing, spraying and combinations thereof. It is noted that the aforementioned methods of applying the chemical cleaning process have been provided for illustrative purposes only, and are not intended to limit the present disclosure. Any method of applying the chemical cleaning process to the deposition surface of the semiconductor substrate may be employed.

In a following step 20, the semiconductor substrate is positioned within an epitaxial deposition chamber. The epitaxial deposition chamber includes any chamber that may be employed in epitaxial deposition. For example, the epitaxial deposition chamber may include the deposition chamber of a chemical vapor deposition (CVD) apparatus.

In some embodiments, once the semiconductor substrate is positioned within the epitaxial deposition chamber, the deposition surface of the semiconductor substrate may be treated with a hydrogen (H₂) containing gas at a pre-bake temperature in step 30. Typically, the hydrogen reduces the native oxide (SiO₂) containing oxygen from the deposition surface of the semiconductor substrate. In some embodiments, treating the deposition surface of the semiconductor substrate with a hydrogen containing gas at a pre-bake temperature provides an “oxygen-free” deposition surface. By “oxygen-free” deposition surface it is meant that the deposition surface of the semiconductor substrate is free of oxide. In one embodiment, the oxygen content of the deposition surface is less than 1%. In another embodiment, the oxygen content of the bare surface is less that 0.5%.

In one embodiment, the hydrogen containing gas is comprised of greater than 90% hydrogen (H₂). In another embodiment, the hydrogen containing gas is comprised of 100% hydrogen (H₂). It is noted that the hydrogen containing gas may include other elements, so long as the hydrogen containing gas does not provide a source of oxygen. In one embodiment, the hydrogen containing gas is applied at a pressure ranging from 10 Torr to 600 Torr.

In some embodiments, in which the deposition surface has been chemically cleaned with a cleaning processes that includes a first step of treating the deposition surface of the semiconductor substrate with hydrofluoric acid, a second step of treating the deposition surface of the semiconductor substrate solution of ammonium hydroxide and hydrogen peroxide, and a third step of treating the deposition surface with an aqueous mixture of hydrochloric acid and an oxidizing agent, the temperature of the hydrogen containing gas treatment may range from 750° C. to 850° C. In one example, the temperature of the hydrogen containing gas treatment that follows the three step chemical cleaning process is on the order of 800° C.

The temperature of the hydrogen containing gas treatment is referred to as the “pre-bake temperature”. In some embodiments, in which the deposition surface has not been chemically cleaned with a hydrofluoric acid last process, and there remains a native oxide, the pre-bake temperature of the hydrogen containing gas treatment may be greater than 1000° C. For example, the pre-bake temperature of the hydrogen pre-bake process may be greater than 1100° C. In another example, the pre-bake temperature of the hydrogen containing gas treatment that follows the hydrofluoric acid last cleaning process may range from 1100° C. to 1200° C.

The time period for the treatment of the deposition surface of the semiconductor substrate with the hydrogen containing gas may range from 15 seconds to 5 minutes. In another example, the time period for the treatment of the deposition surface of the semiconductor substrate with the hydrogen containing gas may range from 30 seconds to 2 minutes. The above time periods are provided for illustrative purposes only and are not intended to limit the present disclosure, as other time periods may be suitable for the treatment of the deposition surface of the semiconductor substrate with the hydrogen containing gas, so long as the time period by which the hydrogen containing gas is applied to the deposition surface is sufficient to provide a substantially oxygen-free deposition surface.

In one embodiment, the hydrogen containing gas is flown across the deposition surface of the semiconductor substrate at a flow rate of 5000 sccm to 80000 sccm. In another embodiment, the hydrogen containing gas is flown across the deposition surface of the semiconductor substrate at a flow rate of 24000 sccm to 35000 sccm. It is noted that the above flow rates are provided for illustrative purposes only and may vary depending upon the configuration, e.g., size, of the epitaxial deposition chamber.

It has been determined by the Applicants of the present disclosure that the epitaxial growth of film following the treatment of the deposition surface of the semiconductor substrate with the hydrogen containing gas at temperatures below 500° C. is delayed by hydrogen from the hydrogen containing gas that is absorbed on the deposition surface of the semiconductor substrate. More specifically, when the semiconductor substrate is composed of silicon, hydrogen from the hydrogen containing gas bonds with the silicon of the deposition surface providing a deposition surface that is terminated with silicon-hydrogen bonds. The silicon-hydrogen bonds that are formed on the deposition surface can obstruct epitaxial deposition resulting in long nucleation time on Si surfaces

It has been further determined that the application of a gas flow comprised of at least one of hydrochloric acid, germane, and dichlorosilane across the deposition surface of the semiconductor substrate as the temperature decreases from the pre-bake temperature to the epitaxial deposition temperature substantially reduces, if not eliminates the “nucleation effect” observed in high Ge fraction SiGe and 100% Ge grown layers on bare Si surfaces. This effect is not due to silicon hydrogen surface coverage but due to at least 2 mL of germanium growth due to the influx of hydrochloric acid (HCl), germane and dichlorosilane (DCS) during the cool down to deposition temperature. There are two distinct growth rates for pure germanium films grown directly on silicon. A very low growth rate at the initial growth, and a much higher growth rate as a few monolayers of germanium have deposited. The low growth rate related to germanium growth on silicon, and the high growth rate related to germanium growth on germanium. This same phenomena is seen with high % silicon germanium layers.

Following the hydrogen gas treatment, in step 40 of the process flow that is depicted in FIG. 1, the deposition surface of the semiconductor substrate is treated with a gas flow that is composed of at least one of hydrochloric acid, germane, and dichlorosilane that is introduced to the epitaxial deposition chamber as temperature is decreased from the pre-bake temperature to the epitaxial deposition temperature. In one embodiment, the treating of the deposition surface of the semiconductor substrate with the gas flow comprised of the at least one of the hydrochloric acid, the germanium hydroxide, and the dichlorosilane further includes a carrier gas. For example, the carrier gas may be hydrogen (H₂), helium (He), argon (Ar) or nitrogen (N₂) gas. The carrier gas may comprise greater than 85% by volume of the gas flow. In another embodiment, the carrier gas may comprise greater than 90% by volume of the gas flow.

In one embodiment, the gas flow is comprised of 90% by volume or greater of a carrier gas, such as hydrogen, 1% to 10% by volume of hydrochloric acid and a remainder of germane. In one embodiment, the ratio of hydrochloric acid to germane ranges from 2:1 to 5:1. In one embodiment, the ratio of hydrochloric acid to germane is 3:1.

In one embodiment, the gas flow is comprised of 90% by volume or greater of a carrier gas, such as hydrogen, 1% to 10% by volume of hydrochloric acid, less than 10% by volume of germane, and less than 10% by volume dichlorosilane. In one embodiment, the ratio of hydrochloric acid to germane to dichlorosilane ranges from 2:1:1 to 20:4:1. In one embodiment, the ratio of hydrochloric acid to germane to dichlorosilane is 10:3.5:1.

In one example, a gas flow comprised of 90% by volume or greater of a carrier gas, such as hydrogen, 1% to 10% by volume of hydrochloric acid, less than 10% by volume of germane, and less than 10% by volume dichlorosilane is applied to the deposition surface of the semiconductor substrate at a flow rate ranging from 5000 sccm to 80000 sccm. In another example, a gas flow comprised of 90% by volume or greater of a carrier gas, such as hydrogen, 1% to 10% by volume of hydrochloric acid, less than 10% by volume of germane, and less than 10% by volume dichlorosilane is applied to the deposition surface of the semiconductor substrate at a flow rate ranging of 21100 sccm.

The inclusion of dichlorosilane in the gas flow can increase the uniformity of the subsequently formed epitaxial layer. More specifically, the inclusion of dichlorosiliane in the gas flow can increase the quality of the subsequently formed epitaxially deposited material layer. For example, the incorporation of dichlorosilane in the gas flow that includes hydrochloric acid and a remainder of germane can eliminate island formation in the subsequently formed epitaxial layer. It is noted that dichlorosiliane is optional, and may be omitted.

The gas flow that is composed of at least one of hydrochloric acid, germane, and dichlorosilane is introduced to the epitaxial deposition chamber as the temperature decreases from the pre-bake temperature to the epitaxial deposition temperature. The “epitaxial deposition temperature” is the temperature at which the source gasses for deposition of the epitaxial layer are introduced to the epitaxial deposition chamber. In one embodiment, the epitaxial deposition temperature is less than 500° C. In another embodiment, the epitaxial deposition temperature ranges from 250° C. to 450° C. In one example, the epitaxial deposition temperature is about 400° C.

In one embodiment, the rate at which the temperature decreases from the pre-bake temperature to the epitaxial deposition temperature while the deposition surface of the semiconductor substrate is being treated with the gas flow that is composed of at least one of hydrochloric acid, germane and dichlorosilane ranges from 0.5° C. to 3° C. per second. In one example, the rate at which the temperature decreases pre-bake temperature to the epitaxial deposition temperature is 2° C. per second. The time period by which the temperature decreases from the pre-bake temperature to the epitaxial deposition temperature may range from 1 minutes to 16 minutes. In one example, the time period by which the temperature decreases from the pre-bake temperature to the epitaxial deposition temperature may range from 2 minutes to 5 minutes.

Referring to FIG. 1, in step 50 at least one source gas may be applied to the deposition surface of the semiconductor substrate for epitaxial deposition of a material layer (hereafter referred to as an “epitaxial layer”). In an epitaxial deposition process, the chemical reactants provided by the source gasses are controlled and the system parameters are set so that the depositing atoms arrive at the deposition surface of the semiconductor substrate with sufficient energy to move around on the surface and orient themselves to the crystal arrangement of the atoms of the deposition surface.

In one embodiment, the epitaxial layer may be composed of silicon (Si). A number of different sources may be used for the deposition of epitaxial silicon. In some embodiments, the silicon containing gas sources for epitaxial growth include silane (SiH₄), disilane (Si₂H₆), trisilane (Si₃H₈), tetrasilane (Si₄H₁₀), hexachlorodisilane (Si₂Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂) and combinations thereof. The temperature for epitaxial silicon deposition typically ranges from 250° C. to 900° C. Although higher temperature typically results in faster deposition, the faster deposition may result in crystal defects and film cracking.

In another embodiment, the epitaxial layer may be composed of germanium (Ge). A number of different sources may be used for the deposition of epitaxial germanium. In some embodiments, the germanium containing gas sources for epitaxial growth include germane (GeH₄), digermane (Ge₂H₆), halogermane, dichlorogermane, trichlorogermane, tetrachlorogermane and combinations thereof.

In yet another embodiment, the epitaxial layer is composed of silicon germanium (SiGe). A number of different sources may be used for the deposition of epitaxial silicon germanium. In some embodiments, the gas source for the deposition of epitaxial SiGe may include a mixture of silicon containing gas sources and germanium containing gas sources. For example, an epitaxial layer of silicon germanium may be deposited from the combination of a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof, and a germanium gas source that is selected from the group consisting of germane, digermane, halogermane, dichlorogermane, trichlorogermane, tetrachlorogermane and combinations thereof.

The germanium content of the epitaxial layer of silicon germanium may range from 5% to 70%, by atomic weight %. In another embodiment, the germanium content of the epitaxial layer of silicon germanium may range from 10% to 40%.

In an even further embodiment, the epitaxial layer is composed of silicon doped with carbon (Si:C). The carbon (C) content of the epitaxial grown silicon doped with carbon may range from 0.3% to 5%, by atomic weight %. In another embodiment, the carbon content of the epitaxial grown silicon doped with carbon may range from 1% to 2%.

The nucleation time for the epitaxial layer is less than 2000 seconds. The “nucleation time” is the time period that follows the introduction of the source gas for the epitaxially deposited material ending at the point at which epitaxial growth can be measured. In another embodiment, the nucleation time ranges from 0 seconds to 110 seconds. In another embodiment, the nucleation time ranges from 0 seconds to 35 seconds.

It is noted that the following examples are for illustrative purposes only and are not intended to limit the present disclosure.

### EXAMPLES

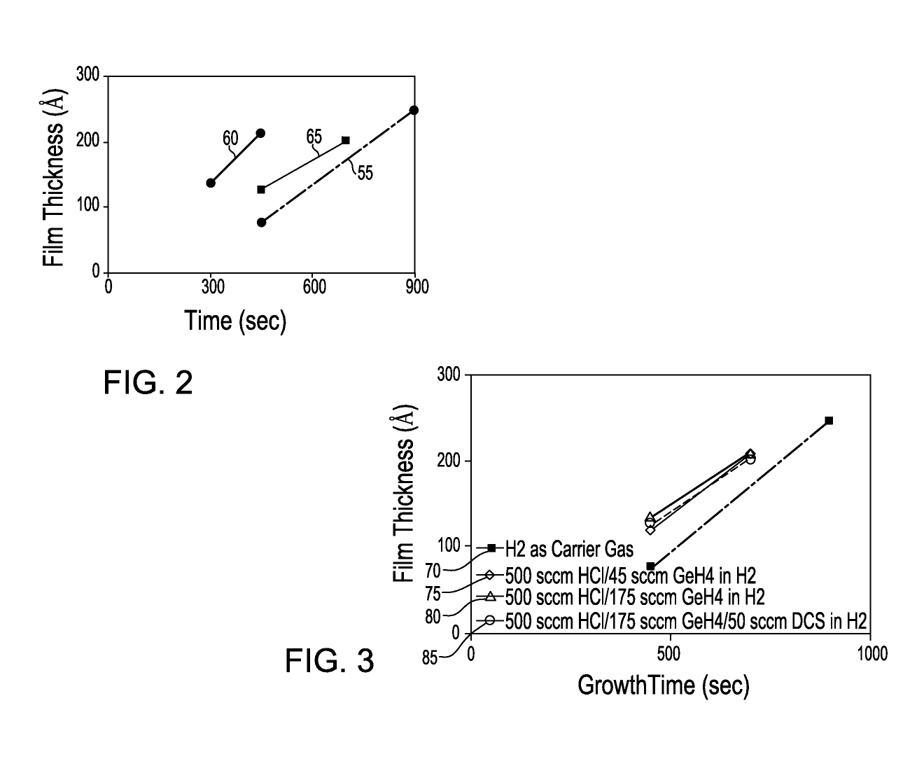

FIG. 2 is a plot of film thickness (Å) of an epitaxially grown silicon germanium layer as a function of the time (seconds) for the epitaxial growth of the silicon germanium. Plot line 55 is a plot of silicon germanium epitaxial growth at 410° C. on a silicon substrate following a pre-bake cleaning process in a hydrogen atmosphere. Plot line 60 is a plot of silicon germanium epitaxial growth at 410° C. on a silicon substrate following a pre-bake cleaning process in a helium (He) atmosphere. Plot line 65 is a plot of silicon germanium epitaxial growth on a silicon substrate including a pre-bake cleaning process in an hydrogen atmosphere followed by a cool down process to an epitaxial deposition temperature of approximately 410° C. in an atmosphere including a gas flow of 500 sccm hydrochloric acid, 175 sccm germane, and 50 sccm dichlorosilane with hydrogen carrier gas. The deposition surfaces of each of the semiconductor substrates on which the epitaxially formed silicon germanium was formed were chemically cleaned using the chemical cleaning methods described above.

The epitaxially grown silicon germanium layer that was formed on the semiconductor substrate after the pre-bake cleaning process in a hydrogen atmosphere had a nucleation time of 245 seconds. A high nucleation time denotes a deposition surface that is occupied by hydrogen adsorption. For example, a deposition surface of a silicon substrate terminated with silicon hydrogen bonds, such as one that results from a pre-bake cleaning process in hydrogen, has a high nucleation time. In comparison to the nucleation time of the epitaxially grown silicon germanium formed on a semiconductor substrate after a pre-bake cleaning process in a hydrogen atmosphere, the silicon germanium epitaxially deposited layer on a semiconductor substrate that was formed after a pre-bake cleaning process in a helium (He) atmosphere had a nucleation time of 40 seconds. The helium pre-bake process does not introduce hydrogen to the deposition surface. Comparison of the nucleation time of the epitaxially formed silicon germanium layer that follows the pre-bake cleaning process in hydrogen to the nucleation time of the epitaxially formed silicon germanium layer that follows the pre-bake cleaning process in helium is evidence of the effect of hydrogen bonding on the surface of the silicon substrate on the epitaxial growth of silicon germanium.

The nucleation time was 31 seconds for the silicon germanium that was formed on the silicon substrate treated with the pre-bake cleaning process in an hydrogen atmosphere followed by the cool down process to an epitaxial deposition temperature of approximately 410° C. in the atmosphere of the gas flow of 500 sccm hydrochloric acid, 175 sccm germane, and 50 sccm dichlorosilane with hydrogen carrier gas. The nucleation time of the epitaxially formed silicon germanium on the silicon deposition surface treated with the cleaning process including the gas flow of hydrochloric acid (HCl), germane (GeH₄), and dichlorosilane (H₂SiCl₂) with hydrogen carrier gas indicated a clean deposition surface free of silicon hydrogen bonding.

FIG. 3 is a plot of film thickness (Å) of an epitaxially grown silicon germanium layer as a function of the time (seconds) for the epitaxial growth of the silicon germanium. Plot line 70 is a plot of the epitaxial growth of silicon germanium following a pre-bake cleaning process in an atmosphere that does not include hydrochloric acid, germane, and dichlorosilane. The silicon germanium epitaxial layer that provided the data in plot line 70 was formed on a silicon substrate following a pre-bake cleaning process in a hydrogen (H₂) atmosphere. The nucleation time for the silicon germanium epitaxial layer that provided the data in plot line 70 was 245 seconds. Plot line 70 is a comparative example.

Plot line 75 was provided by an epitaxially grown silicon germanium layer that was formed on a deposition surface of a silicon substrate treated with a pre-bake cleaning process in an hydrogen atmosphere followed by a cool down process to an epitaxial deposition temperature of approximately 410° C. in an atmosphere including a gas flow of 500 sccm hydrochloric acid, and 45 sccm germane with an hydrogen carrier gas. The nucleation time for the silicon germanium epitaxial layer that provided the data in plot line 75 was 104 seconds. Plot line 80 was provided by an epitaxially grown silicon germanium layer that was formed on a deposition surface of a silicon substrate treated with a pre-bake cleaning process in an hydrogen atmosphere followed by a cool down process to an epitaxial deposition temperature of approximately 410° C. in an atmosphere including a gas flow of 500 sccm hydrochloric acid, and 175 sccm germane with an hydrogen carrier gas. The nucleation time for the silicon germanium epitaxial layer that provided the data in plot line 80 was 0 seconds. Plot line 85 was provided by an epitaxially grown silicon germanium layer that was formed on a deposition surface of a silicon substrate treated with a pre-bake cleaning process in an hydrogen atmosphere followed by a cool down process to an epitaxial deposition temperature of approximately 410° C. in an atmosphere including a gas flow of 500 sccm hydrochloric acid, 175 sccm germane and 50 sccm dichlorosilane with an argon carrier gas. The nucleation time for the silicon germanium epitaxial layer that provided the data in plot line 85 was 31 seconds.

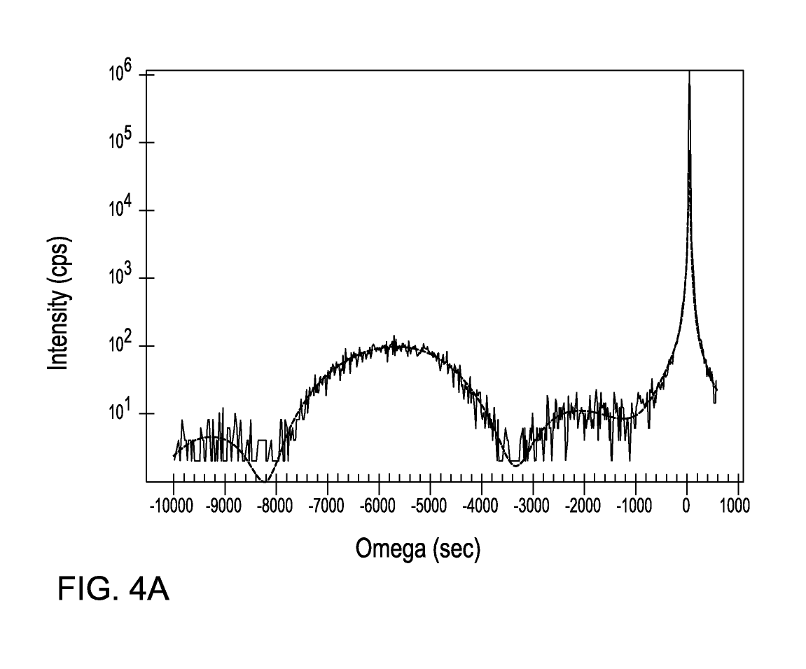

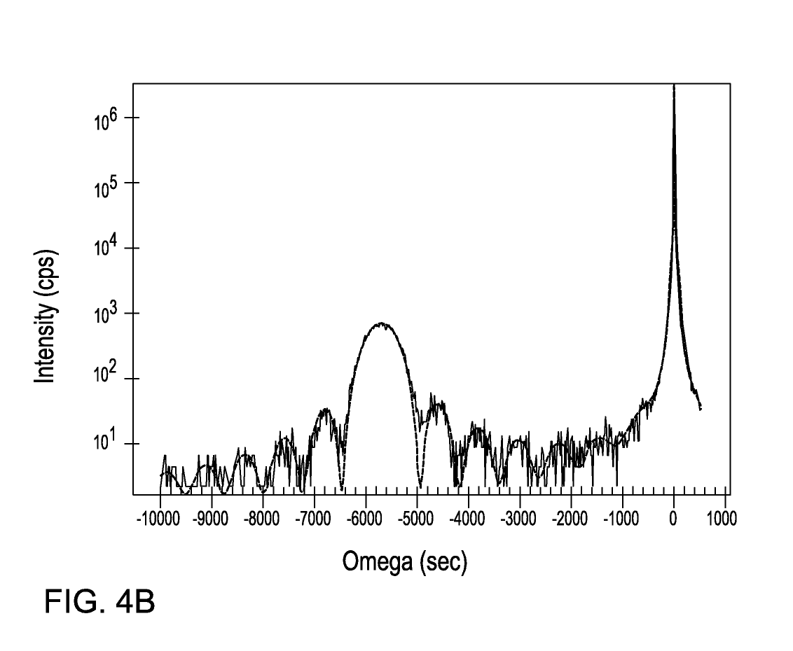

FIG. 4A is a plot of x-ray diffraction (XRD) of an epitaxially grown silicon germanium layer with a growth time of 450 seconds formed after a cleaning process in an atmosphere that does not include hydrochloric acid. The cleaning process utilized to provide the data in FIG. 4A includes a pre-bake cleaning process in a hydrogen atmosphere. FIG. 4B is a plot of x-ray diffraction of an epitaxially grown silicon germanium layer with a growth time of 900 seconds, wherein the deposition surface was prepared in a similar manner to the deposition surface that the epitaxially deposited silicon germanium layer was formed on for the plot in FIG. 4A. The deposited thickness of the epitaxial silicon germanium layer in FIG. 4A is 78 Å and the deposited thickness of the epitaxial silicon germanium layer in FIG. 4B is 248 Å. In FIGS. 4A and 4B the broken, i.e., dashed line, represents the reference data for an epitaxial silicon germanium layer, whereas the solid line represents the measured x-ray diffraction data for the epitaxial silicon germanium layer formed after a cleaning process in an atmosphere that does not include hydrochloric acid. The closer the measured x-ray diffraction data matches the reference data for the epitaxial silicon germanium layer, the higher the quality of the epitaxially deposited silicon germanium. Both FIG. 4A and FIG. 4B show good fitting between experimental data and reference data.

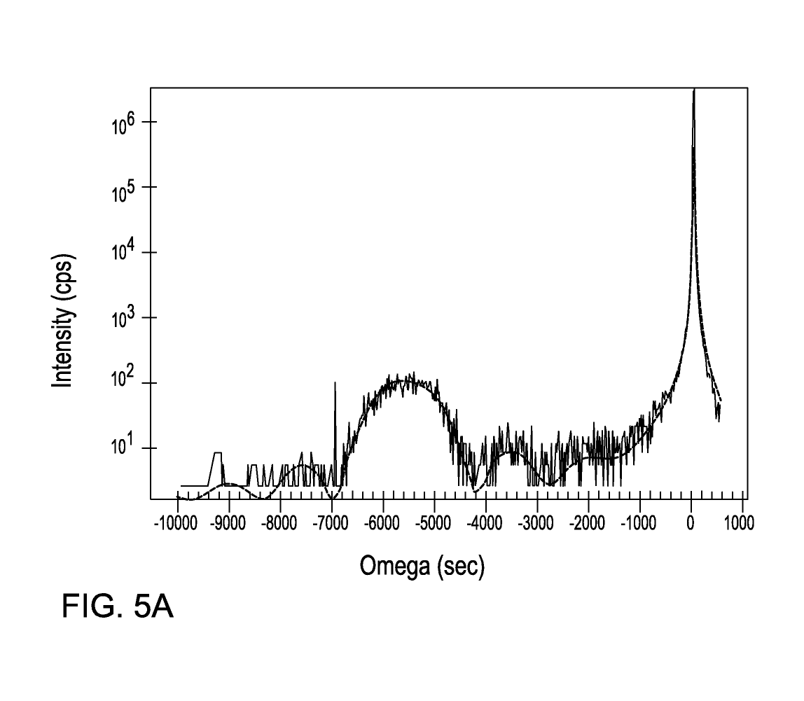

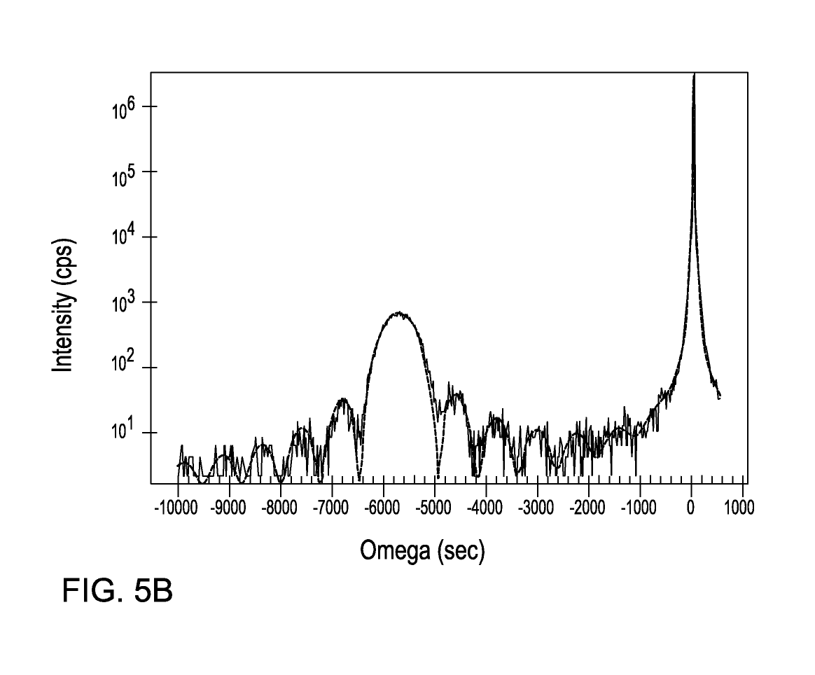

FIG. 5A is a plot of x-ray diffraction of an epitaxially grown silicon germanium (SiGe) layer with a growth time of 450 seconds formed after the deposition surface of a silicon substrate was treated with a pre-bake cleaning process in an hydrogen atmosphere followed by a cool down process to an epitaxial deposition temperature of approximately 410° C. in an atmosphere including a gas flow of 500 sccm hydrochloric acid, and 175 sccm germane with an hydrogen carrier gas. FIG. 5B is a plot of x-ray diffraction of an epitaxially grown silicon germanium layer with a growth time of 900 seconds, wherein the deposition surface was prepared in a similar manner to the deposition surface that the epitaxially deposited silicon germanium layer was formed on for the plot in FIG. 5A. The deposited thickness of the epitaxial silicon germanium layer in FIG. 5A is 136 Å and the deposited thickness of the epitaxial silicon germanium layer in FIG. 5B is 208 Å. In FIGS. 5A and 5B the broken, i.e., dashed line, represents the reference data for an epitaxial silicon germanium layer, whereas the solid line represents the measured x-ray diffraction data for the epitaxially grow silicon germanium layer that employed the gas flow composed of 500 sccm hydrochloric acid, 175 sccm germane, and an hydrogen carrier gas. Both FIG. 5A and FIG. 5B have less perfect fitting between experimental data and reference data.

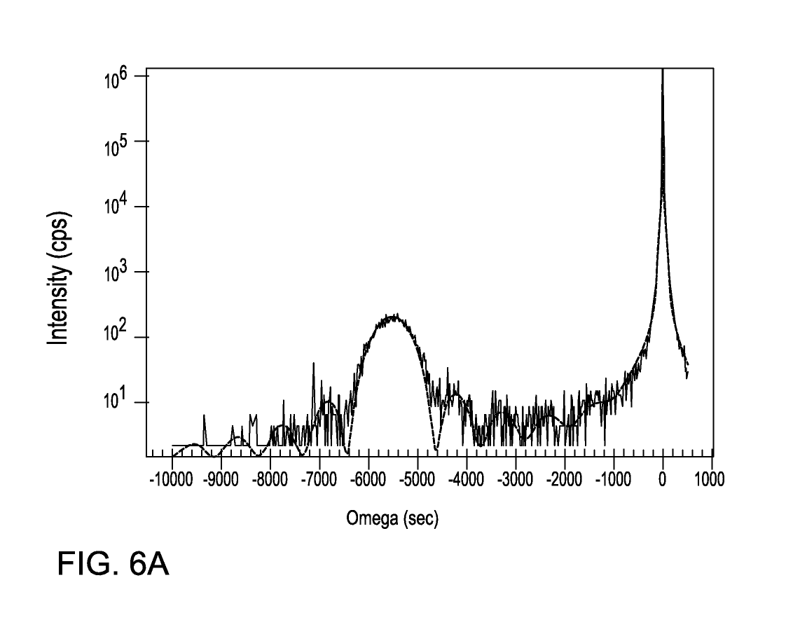

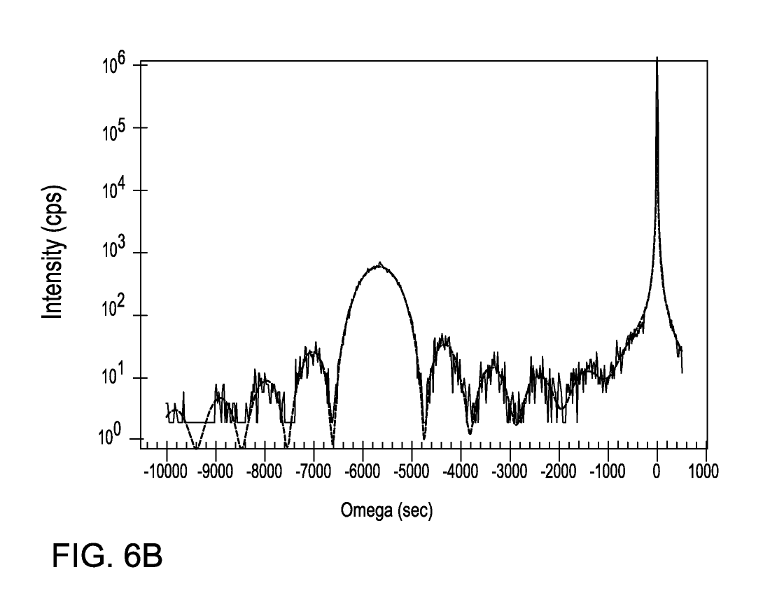

FIG. 6A is a plot of x-ray diffraction of an epitaxially grown silicon germanium layer with a growth time of 450 seconds formed after the deposition surface of a silicon substrate was treated with a pre-bake cleaning process in an hydrogen atmosphere followed by a cool down process to an epitaxial deposition temperature of approximately 410° C. in an atmosphere including a gas flow of 500 sccm hydrochloric acid, 175 sccm germane, and 50 sccm dichlorosilane with an argon carrier gas. FIG. 6B is a plot of x-ray diffraction of an epitaxially grown silicon germanium layer with a growth time of 900 seconds, wherein the deposition surface was prepared in a similar manner to the deposition surface that the epitaxially deposited silicon germanium layer was formed on for the plot in FIG. 6A. The deposited thickness of the epitaxial silicon germanium layer in FIG. 6A is 127 Å and the deposited thickness of the epitaxial silicon germanium layer in FIG. 6B is 203 Å. In FIGS. 6A and 6B the broken, i.e., dashed line, represents the reference data for an epitaxial silicon germanium layer, whereas the solid line represents the measured x-ray diffraction data for the epitaxially grow silicon germanium layer that employed the gas flow composed of 500 sccm hydrochloric acid, 175 sccm germane, and 50 sccm dichlorosilane with an argon carrier gas. Both FIG. 6A and FIG. 6B show perfect fitting between experimental data and reference data. Therefore, the film quality was improved by introducing dichlorosilane to the flow during the cooling down process.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method of depositing an epitaxial layer comprising:
chemically cleaning a deposition surface of a semiconductor substrate;
treating the deposition surface of the semiconductor substrate with a hydrogen containing gas at a pre-bake temperature;
treating the deposition surface of the semiconductor substrate with a gas flow comprised of at least one of hydrochloric acid (HCl), germane (GeH₄), and dichlorosilane (H₂SiCl₂) that is introduced to the epitaxial deposition chamber as temperature is decreased from the pre-bake temperature to an epitaxial deposition temperature; and
applying at least one source gas for epitaxial deposition of a material layer to the deposition surface.

2. The method of claim 1, wherein the chemically cleaning of the deposition surface comprises treating the deposition surface of the semiconductor substrate with hydrofluoric (HF) acid before the treating of the deposition surface of the semiconductor substrate with a hydrogen containing gas.

3. The method of claim 2, wherein the treating of the deposition surface of the semiconductor substrate with a hydrogen containing gas at the pre-bake temperature comprises an atmosphere comprised of 100% hydrogen (H₂), and the pre-bake temperature ranging from 750° C. to 850° C.

4. The method of claim 1, wherein the chemically cleaning of the deposition surface comprises a cleaning sequence that includes first treating the deposition surface of the semiconductor substrate with hydrofluoric (HF) acid, second treating the deposition surface of the semiconductor substrate with a solution of ammonium hydroxide (NH₄OH) and hydrogen peroxide (H₂O₂) and third treating the deposition surface with an aqueous mixture of hydrochloric acid (HCl) and an oxidizing agent selected from the group consisting of H₂O₂, O₃ and combinations thereof.

5. The method of claim 4, wherein the treating of the deposition surface of the semiconductor substrate with a hydrogen containing gas at the pre-bake temperature comprises an atmosphere comprised of 100% hydrogen (H₂), and the pre-bake temperature greater than 1000° C.

6. The method of claim 1, wherein the treating of the deposition surface of the semiconductor substrate with the gas flow comprised of the at least one of the hydrochloric acid (HCl), the germane (GeH₄) and the dichlorosilane (H₂SiCl₂) further comprises a carrier gas, wherein the carrier gas is at least 90% by volume of the gas flow, the hydrochloric acid (HCl) has a volume of the gas flow ranging from 1% to 10%, the germane (GeH₄) has a volume of the gas flow less than 10%, and the dichlorosilane (H₂SiCl₂) has a volume of the gas flow less than 1% to 10%.

7. The method of claim 1, wherein the epitaxial deposition temperature is less than 500° C., and a time period for which said temperature is decreased from the pre-bake temperature to the epitaxial deposition temperature ranges from 1 minutes to 16 minutes.

8. A method of depositing an epitaxial layer comprising:
positioning a semiconductor substrate in an epitaxially deposition chamber;
treating a deposition surface of the semiconductor substrate with a hydrogen containing gas at a temperature greater than 750° C.;
treating the deposition surface of the semiconductor substrate with a gas flow comprised of at least one of hydrochloric acid (HCl), germane (GeH₄), and dichlorosilane (H₂SiCl₂) that is introduced to the epitaxial deposition chamber as temperature is decreased to less than 500° C.; and
applying source gasses for epitaxial deposition of a material layer to the deposition surface.

9. The method of claim 8, wherein the treating of the deposition surface of the semiconductor substrate with the gas flow comprised of the at least one of the hydrochloric acid (HCl), the germane (GeH₄), and the dichlorosilane (H₂SiCl₂) further comprises a carrier gas, wherein the carrier gas is at least 90% by volume of the gas flow, the hydrochloric acid (HCl) has a volume of the gas flow ranging from 1% to 10%, the germane (GeH₄) has a volume of the gas flow less than 10%, and the dichlorosilane (H₂SiCl₂) has a volume of the gas flow less than 1% to 10%.

10. The method of claim 8, wherein the applying of the at least one source gas for the epitaxial deposition of the material layer to a deposition surface comprises at least one of a silicon gas source and a germanium gas source, wherein the silicon gas source is selected from the group consisting of silane (SiH₄), disilane (Si₂H₆), trisilane (Si₃H₈), tetrasilane (Si₄H₁₀), hexachlorodisilane (Si₂Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂) and combinations thereof, and the germanium gas source is selected from the group consisting of germane, digermane, halogermane, dichlorogermane, trichlorogermane, tetrachlorogermane and combinations thereof.
